(19) United States
(12) Patent Application Publication
(10) Pub. No.: US 2024/0215278 A1
(43) Pub. Date: Jun. 27, 2024

(54) DISPLAY DEVICE AND METHOD OF MANUFACTURING THE SAME

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 18/389,834

(22) Filed: Dec. 20, 2023

(30) Foreign Application Priority Data
Dec. 26, 2022 (JP) 2022-208347
Nov. 17, 2023 (JP) 2023-195962

(51) Int. Cl. H10K 50/11; H10K 59/12

(52) U.S. Cl. CPC H10K 50/11; H10K 59/1201; H10K 2101/40

(57) ABSTRACT

According to one embodiment, a display device has such configuration that each of ΔE1_LUMO and ΔE1_HOMO is 0.35 eV or less (ΔE1≤0.35 eV), each of ΔE2_LUMO and ΔE2_HOMO is 0.1 eV or more and 0.5 eV or less (0.1 eV≤ΔE2≤0.5 eV), the light emitting layer includes a first material and a second material, a band gap of the first material is larger than a band gap of the second material, and a ratio of the first material to the second material is 5% or more and less than 40%.

### CROSS-REFERENCE TO RELATED APPLICATIONS

This application is based upon and claims the benefit of priority from Japanese Patent Application No. 2022-208347, filed Dec. 26, 2022; and No. 2023-195962, filed Nov. 17, 2023, the entire contents of all of which are incorporated herein by reference.

### FIELD

Embodiments described herein relate generally to a display device and a method of manufacturing the display device.

### BACKGROUND

In recent years, display devices which use organic electroluminescent (EL) light emitting materials have been developed. Such display devices include an organic EL layer that contains light emitting materials. In the organic layer of the organic EL element, as electrons and holes recombine each other, the light emitting material is excited, and when the light emitting material returns to its ground state, emission occurs.

### BRIEF DESCRIPTION OF THE DRAWINGS

FIG. 1 is an overall perspective view showing a display device of an embodiment.

FIG. 2 is a partial plan view schematically showing a configuration example of the display device.

FIG. 3 is a cross-sectional view of the display device taken along line A1-A2 shown in FIG. 2.

FIG. 4 is a partially enlarged cross-sectional view illustrating a pixel electrode, an organic EL layer and a common electrode.

FIG. 5 is a diagram showing energy bands of a display device of Comparative Example 1.

FIG. 6 is a diagram showing energy bands of a display device of Comparative Example 2.

FIG. 7 is a diagram showing energy bands of a display device having a staggered structure of the embodiment.

FIG. 8 is a diagram showing energy bands of a display device having a well-like structure of the embodiment.

FIG. 9 is a diagram illustrating a point source deposition method.

FIG. 10 is a diagram illustrating a linear scan deposition method.

FIG. 11 is a diagram illustrating a decrease in light emission efficiency.

FIG. 12 is a diagram illustrating a luminance versus time in the configuration of the embodiment.

FIG. 13 is a diagram illustrating occurrence of coarseness and denseness in the light emitting layer.

FIG. 14 is a diagram showing a calibration curve of light emission against the composition of the light emitting layer.

FIG. 15 is a diagram showing a calibration curve of light emission against the composition of the light emitting layer.

FIG. 16 is a diagram illustrating a time-resolved measurement of luminance.

### DETAILED DESCRIPTION

In general, according to one embodiment, a display device comprises
an anode;
an organic EL layer including a hole injection layer, a hole transport layer, an electron blocking layer, a light emitting layer, a hole blocking layer, an electron transport layer and an electron injection layer; and
a cathode, wherein
ΔE1_LUMO is defined as a potential barrier between the electron injection layer, and the electron transport layer and the hole blocking layer,
ΔE1_HOMO is defined as a potential barrier between the hole injection layer, and the hole transport layer and the electron blocking layer,
each of ΔE1_LUMO and ΔE1_HOMO is 0.35 eV or less (ΔE1≤0.35 eV),
ΔE2_LUMO is defined as a potential barrier between the electron transport layer and the hole blocking layer, and the light emitting layer,
ΔE2_HOMO is defined as a potential barrier between the hole transport layer and the electron blocking layer, and the light emitting layer,
each of ΔE2_LUMO and ΔE2_HOMO is 0.1 eV or more and 0.5 eV or less (0.1 eV≤ΔE2≤0.5 eV),
the light emitting layer includes a first material and a second material,
a band gap of the first material is larger than a band gap of the second material, and
a ratio of the first material to the second material is 5% or more and less than 40%.

According to another embodiment, a method for manufacturing a display device, wherein the display device comprises
an anode;
an organic EL layer including a hole injection layer, a hole transport layer, an electron blocking layer, a light emitting layer, a hole blocking layer, an electron transport layer and an electron injection layer; and
a cathode,
ΔE1_LUMO is defined as a potential barrier between the electron injection layer, and the electron transport layer and the hole blocking layer,
ΔE1_HOMO is defined as a potential barrier between the hole injection layer, and the hole transport layer and the electron blocking layer,
each of ΔE1_LUMO and ΔE1_HOMO is 0.35 eV or less (ΔE1≤0.35 eV),
ΔE2_LUMO is defined as a potential barrier between the electron transport layer and the hole blocking layer, and the light emitting layer,
ΔE2_HOMO is defined as a potential barrier between the hole transport layer and the electron blocking layer, and the light emitting layer,
each of ΔE2_LUMO and ΔE2_HOMO is 0.1 eV or more and 0.5 eV or less (0.1 eV≤ΔE2≤0.5 eV),
the light emitting layer includes a first material and a second material,
a band gap of the first material is larger than a band gap of the second material,
a ratio of the first material to the second material is 5% or more and less than 40%, and
the method comprising:
forming the light emitting layer by a linear scan evaporation method using a linearly arranged evaporation sources.

An object of this embodiment is to provide a display device in which the effect of phase separation of the light emitting layer can be suppressed and the light emission efficiency can be improved.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### Embodiments

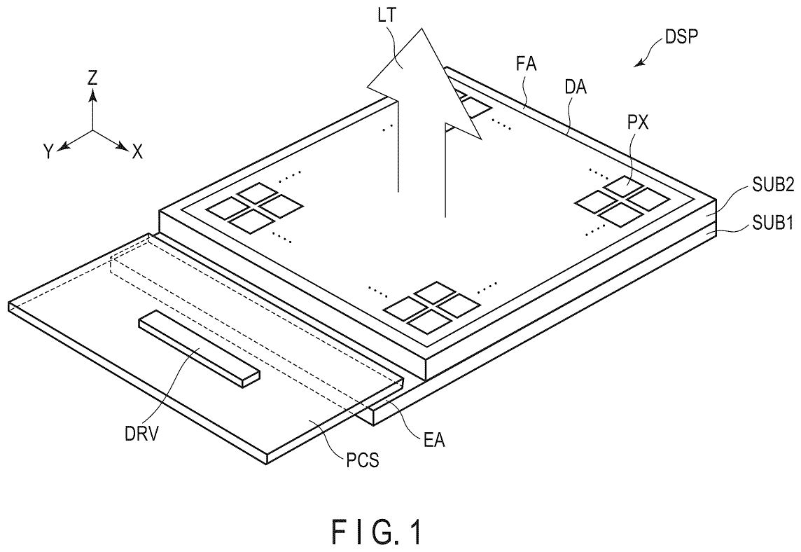

FIG. 1 is an overall perspective view of a display device of an embodiment. A display device DSP comprises a display area DA and a peripheral area FA provided around the display area DA on a substrate SUB1. The display device DSP includes a plurality of pixels PX arranged in the display area DA. In the display device DSP, light LT from the rear surface is transmitted to the front surface and vice versa.

On an upper surface of the display area DA, a substrate SUB2 is provided as a sealing member. The substrate SUB2 is fixed to the substrate SUB1 by a seal material (not shown) provided to surround the display area DA. The display area DA formed on the substrate SUB1 is sealed so as not to be exposed to the atmosphere by the substrate SUB2 as a sealing member and the sealing material.

An area EA in an end portion of the substrate SUB1 is located outside of the substrate SUB2. In the area EA, a wiring circuit board PCS is provided. On the wiring circuit board PCS, a drive element DRV that outputs video signals and drive signals is provided. Signals from the drive element DRV are input to the pixels PX in the display area DA via the wiring circuit board PCS. Based on the video signals and various control signals, the pixels PX emits light.

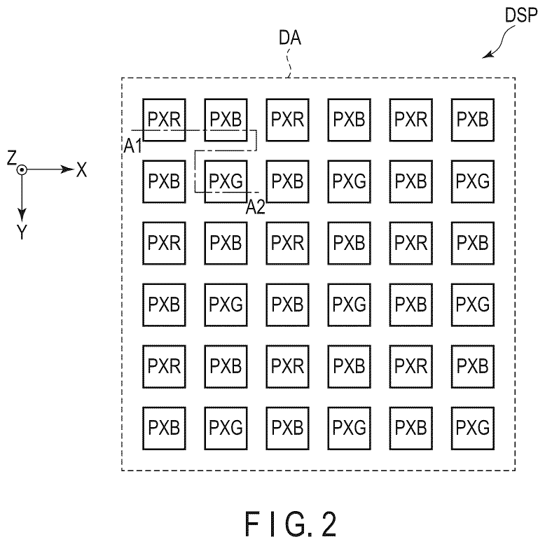

FIG. 2 is a partial plan view schematically showing a configuration example of the display device. The plurality of pixels PX includes pixels PXR which emit red color, pixels PXG which emit green color and pixels PXB which emit blue color. Each pixel PXR is disposed next to respective pixels PXB along the first direction X and the second direction Y. Each pixel PXG is disposed next to respective pixels PXB along the first direction X and the second direction Y. Each pixel PXB is disposed next to a respective pixel PXR along the first direction and next to a respective pixel PXG along the second direction Y.

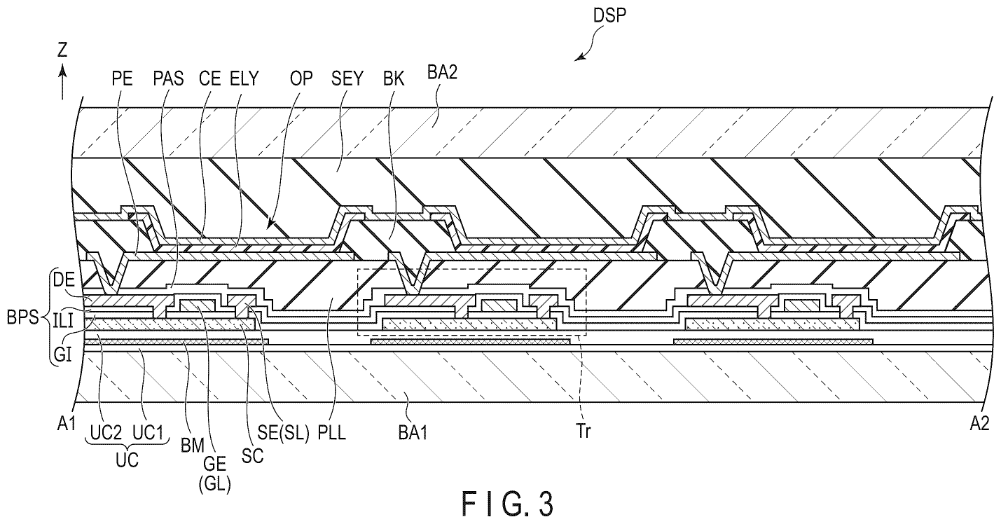

FIG. 3 is a diagram showing a cross-sectional view of the display device taken along line A1-A2 shown in FIG. 2. A base BA1 is, for example, glass or a base material made of a resin material. For example, acrylic, polyimide, polyethylene terephthalate, polyethylene naphthalate or the like may be used as the resin material, and may be formed from a single layer or a stacked body of multiple layers of any of these.

An insulating layer UC1 is provided on the base BA1. The insulating layer UC1 is formed from, for example, a single layer of a silicon oxide film or silicon nitride film or a stacked body of these layers.

On the insulating layer UC1, a light-shielding layer BM may as well be provided to overlap a transistor Tr. The light-shielding layer BM suppresses changes in transistor characteristics, which may be caused by light penetration or the like from the rear surface of the channel of the transistor Tr. When the light-shielding layer BM is formed of a conductive layer, it is also possible to impart a back-gate effect to the transistor Tr by providing a predetermined potential.

An insulating layer UC2 is provided to cover the insulating layer UC1 and the light-shielding layer BM. For the insulating layer UC2, a material similar to that of the insulating layer UC1 can be used. The insulating layer UC2 may as well be made of a material different from that of the insulating layer UC1. For example, silicon oxide can be used for the insulating layer UC1, whereas silicon nitride for the insulating layer UC2. The insulating layers UC1 and UC2 together may be referred to as insulating layer UC.

The transistor Tr is provided on the insulating layer UC. The transistor Tr includes a semiconductor layer SC, an insulating layer GI, a gate electrode GE (a scanning line GL), an insulating layer ILI, a source electrode SE (a signal line SL) and a drain electrode DE.

As the semiconductor layer SC, amorphous silicon, polysilicon or an oxide semiconductor is used. As the insulating layer GI, for example, silicon oxide or silicon nitride is provided in a single layer or in a stacked body of these layers.

For example, a molybdenum-tungsten alloy (MoW) or titanium-aluminum alloy (Ti/Al/Ti) is used as the gate electrode GE. The gate electrode GE may be formed to be integrated with the scanning line GL.

The insulating layer ILI is provided to cover the semiconductor layer SC and the gate electrode GE. The insulating layer ILI is formed, for example, by a single layer of a silicon oxide layer or silicon nitride layer or a stacked body of these layers.

On the insulating layer ILI, the source electrode SE and the drain electrode DE are provided. The source electrode SE and drain electrode DE are connected to the source region and drain region of the semiconductor layer SC, respectively, via contact holes made in the insulating layer ILI and the insulating layer GI. The source electrode SE may as well be formed to be integrated with the signal line SL.

An insulating layer PAS is provided to cover the source electrode SE, the drain electrode DE and the insulating layer ILI. Further, an insulating layer PLL is provided to cover the insulating layer PAS.

The insulating layer PAS is formed using an inorganic insulating material. The inorganic insulating material is, for example, a single layer of silicon oxide or silicon nitride or a stacked body of these. The insulating layer PLL is formed using an organic insulating material. The organic insulating material is, for example, an organic material such as photosensitive acrylic, polyimide or the like. With the insulating layer PLL thus provided, steps caused by the transistor Tr can be planarized.

On the insulating layer PLL, the pixel electrode PE is provided. The pixel electrode PE is connected to the drain electrode DE via contact holes made in the insulating layers PAS and PLL.

The pixel electrode PE is formed from, for example, a three-layer stacked structure of indium zinc oxide (IZO), silver (Ag) and IZO.

In this embodiment, the configuration from the base BA1 to the insulating layer PLL is referred to as a backplane BPS.

A bank BK (which may as well be referred to as a projecting portion or rib) is provided between each adjacent pair of pixel electrodes PE. As the material of the bank BK, an organic material similar to the material of the insulating layer PLL is used. The bank BK is opened to expose a part of the respective pixel electrode PE. Further, it is preferable that an end portion of the opening OP should be gently tapered in cross-sectional view. If the end portion of the opening OP has a steep shape, coverage defects will occur in an organic EL layer ELY that is to be formed later.

The organic EL layer ELY is provided between each adjacent pair of banks BK so as to overlap the respective pixel electrode PE. The organic EL layer ELY includes a hole injection layer HIY, a hole transport layer HTY, an electron blocking layer EBY, a light emitting layer ELL, a hole blocking layer HBY, an electron transport layer ETY and an electron injection layer EIY.

A common electrode CE is provided on the organic EL layer ELY. As the common electrode CE, a magnesium-silver alloy (MgAg) film is formed as a thin film through which the light emitted from the organic EL layer ELY can be transmitted. In this embodiment, the pixel electrode PE serves as an anode and the common electrode CE serves as a cathode. Light emission generated by the organic EL layer ELY is extracted upward via the common electrode CE. In other words, the display device DSP has a top emission structure.

An insulating layer SEY is provided to cover the common electrode CE. The insulating layer SEY has a function of preventing moisture from entering the organic EL layer ELY from the outside. As the insulating layer SEY, a material having a high gas barrier property is preferable. As the insulating layer SEY, for example, a layer obtained by sandwiching an organic insulating layer between two inorganic insulating layers containing nitrogen, can be used. Examples of the material for the organic insulating layer are acrylic resin, epoxy resin and polyimide resin. Examples of the material for the inorganic insulating layer containing nitrogen are silicon nitride and aluminum nitride.

A base BA2 is provided on the insulating layer SEY. The base BA2 is formed of a material similar to that of the base BA1. Between the base BA2 and the insulating layer SEY, a translucent inorganic insulating layer or a translucent organic insulating layer may as well be provided. The organic insulating layer may as well have the function of adhering the insulating layer SEY and the base BA2 together.

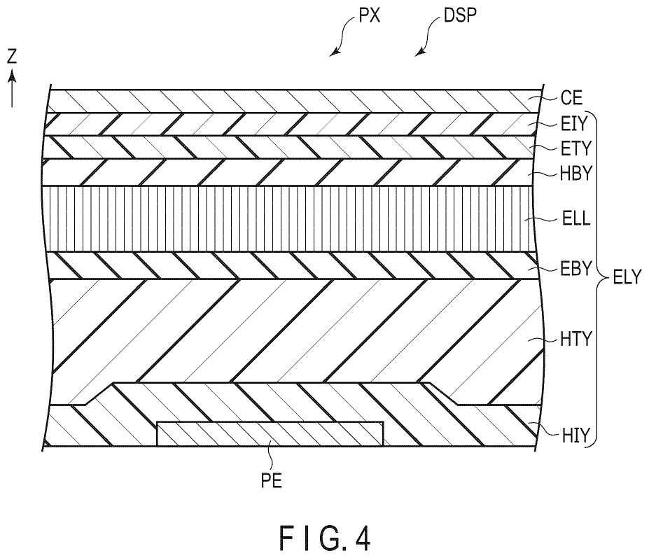

FIG. 4 is a partially enlarged cross-sectional view illustrating the pixel electrode, the organic EL layer and the common electrode. In FIG. 4, the components from the pixel electrode PE to the common electrode CE in each pixel PX are shown. However, the illustration of the bank BK is omitted.

The pixels PX each includes a hole injection layer HIY, a hole transport layer HTY, an electron blocking layer EBY, a light emitting layer ELL, a hole blocking layer HBY, an electron transport layer ETY, an electron injection layer EIY and a common electrode CE on the pixel electrode PE.

Light emission in the organic EL layer ELY is obtained when the light is emitted as the excitation energy of excitons generated by holes injected into the highest occupied molecular orbital (HOMO, generally measured as ionization potential) and electrons injected into the lowest unoccupied molecular orbital (LUMO, generally measured as electron affinity) of the material of the light emitting layer ELL is relaxed.

The hole injection layer HIY, the hole transport layer HTY, the electron blocking layer EBY, the hole blocking layer HBY, the electron transport layer ETY, the electron injection layer EIY and the common electrode CE are provided over the entire surfaces of the plurality of pixels PX. They are formed as so-called solid films.

The material for the hole injection layer HIY is a material having a high efficiency of hole injection from the anode (the pixel electrode PE). The hole transport layer HTY transports the injected holes to the light emitting layer ELL. The electron blocking layer EBY keeps the electrons injected from the cathode (the common electrode CE) in the light emitting layer ELL and prevents them from leaking out to the hole transport layer HTY.

The electron injection layer EIY injects electrons from the cathode, and the electron transport layer ETY transports the injected electrons to the light emitting layer ELL. The hole blocking layer HBY keeps the holes injected from the anode in the light emitting layer ELL and prevents them from leaking out to the electron transport layer ETY.

In the pixels PX of this embodiment, the light from the light-emitting layer ELL is emitted upward or downward. The light emitted upward is extracted to the outside via the common electrode CE. Note that the light emitted downward may be reflected by a reflective layer provided on the pixel electrode PE. On the common electrode CE as well, a reflective layer may be provided and the light reflected thereby may be reflected between each of the pixel electrodes PE and the common electrode CE. With this configuration, of the light emitted by the light-emitting layer ELL, only the light having a resonance wavelength is amplified. As a result, light having high peak intensity and a spectrum of narrow width can be extracted, which makes it possible to expand the color reproduction range of the display device DSP (the microcavity effect).

Further, as to the hole injection layer HIY and the hole transport layer HTY, by lowering the hole injection barrier (the difference between the work function of the anode and the HOMO level of the material of the hole transport layer HTY) from the pixel electrode PE (the anode), holes can be allowed to flow smoothly.

As to the electron injection layer EIY or the electron transport layer ETY, electrons can be allowed to flow smoothly by lowering the electron injection barrier (the difference between the work function of the cathode and the LUMO level of the material of the adjacent electron transport layer ETY) from the common electrode CE (the cathode).

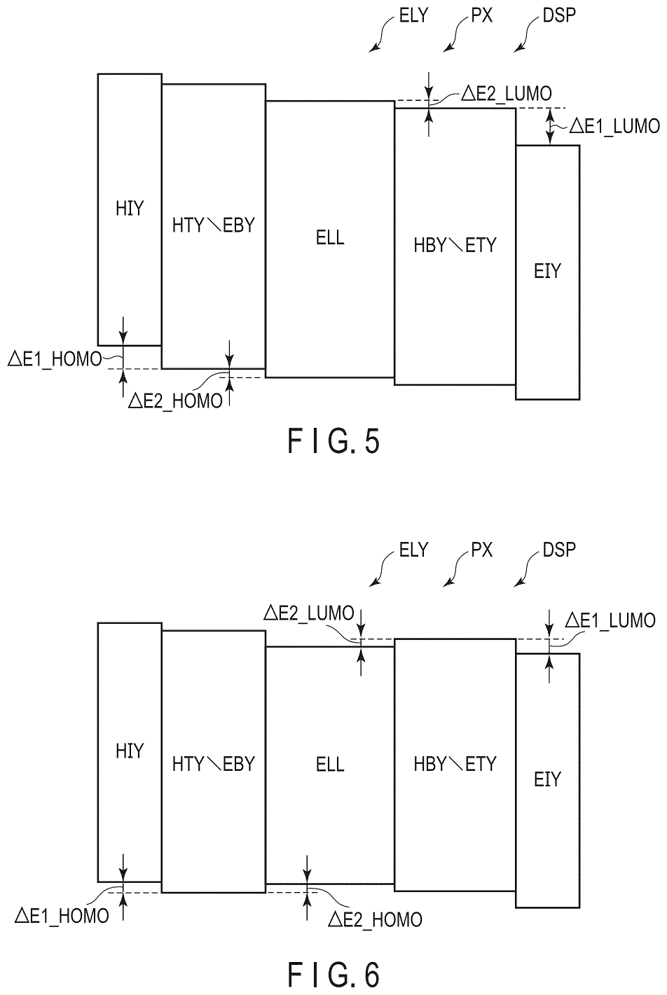

FIG. 5 is a diagram showing the energy bands of a display device of Comparative Example 1. When the hole transport layer HTY is provided between the pixel electrodes PE (the anode) and the light emitting layer ELL, in order to make hole injection and hole transport from the pixel electrode PE more effective, the hole injection material and hole transport material are selected so that a staircase-shaped potential barrier is created in the interface of each layer from the Fermi level of the pixel electrode PE to the HOMO level of the light emitting layer ELL. Such a staircase-shaped potential barrier is referred to as a staggered configuration.

Similarly, when the electron transport layer ETY is provided between the common electrode CE (the cathode) and the light emitting layer ELL, in order to make electron injection and transport from the common electrode CE to be carried out more effective, the electron injection material and transport material are selected so that a staircase-like potential barrier is created in the interface of each layer from the Fermi level of the common electrode CE to the LUMO level of the light emitting layer ELL. With the staircase-shaped potential barrier thus provided, it is possible to improve the properties of the carrier injection to the light emitting layer ELL and enhances the light emission performance.

The potential barrier between the electron injection layer EIY, and the electron transport layer ETY and the hole blocking layer HBY is referred to as ΔE1_LUMO. The potential barrier between the electron transport layer ETY and the hole blocking layer HBY, and the light emitting layer ELL is referred to as ΔE2_LUMO.

By making ΔE1_HOMO and ΔE2_HOMO, which are the hole transport pathways and ΔE1_LUMO and ΔE2_LUMO, which are the electron transport pathways, as small as possible, carriers are allowed to flow smoothly and the voltage (V)-current (I) characteristics (which may as well be referred to as VI characteristics) of the pixel PX can be improved.

FIG. 6 is a diagram showing the energy bands of a display device of Comparative Example 2. In FIG. 6, the HOMO level of the light-emitting layer ELL and the HOMO levels of the adjacent carrier transport layers (a hole transport layer HTY and an electron transport layer ETY) are compared, and the HOMO levels of the carrier transport layers are lower. Also, the LUMO level of the light-emitting layer ELL and the LUMO levels of the adjacent carrier transport layers (a hole transport layer HTY and an electron transport layer ETY) are compared, and the LUMO levels of the carrier transport layers are higher. The potential barriers shown in FIG. 6 is referred to as a well-like structure.

In FIG. 6 as well, the hole transport pathways are ΔE1_HOMO and ΔE2_HOMO, and the electron transport pathways are ΔE1_LUMO and ΔE2_LUMO. ΔE1_HOMO indicates the energy difference in HOMO between materials adjacent to each other. As an example here, the energy difference between the hole injection layer HIY and the hole transport layer HTY is shown. Similarly, ΔE2_HOMO indicates the energy difference in HOMO between the electron blocking layer EBY and the light emitting layer ELL. ΔE1_LUMO indicates the energy difference in LUMO between materials adjacent to each other. As an example here, the energy difference between the electron injection layer EIY and the electron transport layer ETY is shown. Similarly, ΔE2_LUMO indicates the energy difference in LUMO between the hole blocking layer HBY and the light emitting layer ELL.

As described above, in order for the current to flow smoothly, it is preferable that ΔE1_HOMO, ΔE2_HOMO, ΔE1_LUMO and ΔE2_LUMO should be as small as possible.

However, when ΔE2_HOMO and ΔE2_LUMO are excessively small, the V-I characteristics of the organic EL layer ELY may undesirably deteriorate. Note here that the recombination of electrons and holes in the light-emitting layer ELL occurs proportional to the square of the carriers. Therefore, if the light-emitting layer ELL no longer functions as a barrier layer, the confinement of carriers is weakened, which is considered to be a factor of the deterioration of the characteristics. In other words, the advantage that carriers can easily flow into the light emitting layer ELL is as well the disadvantage that carriers can easily flow out of the light emitting layer ELL.

Under these circumstances, in this embodiment, the light-emitting layer ELL is made wide-gap so as to confine the carriers. In this manner, it is possible to make it difficult for carriers to flow out of the light-emitting layer ELL, thereby improving the light emission lifetime of the organic ELY layer.

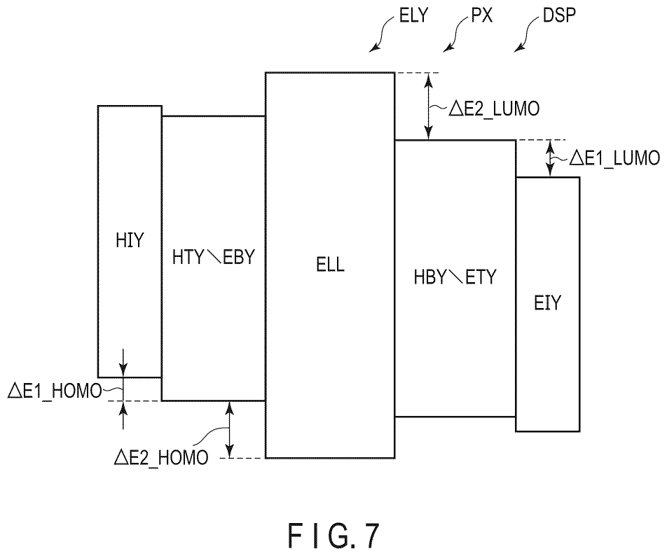

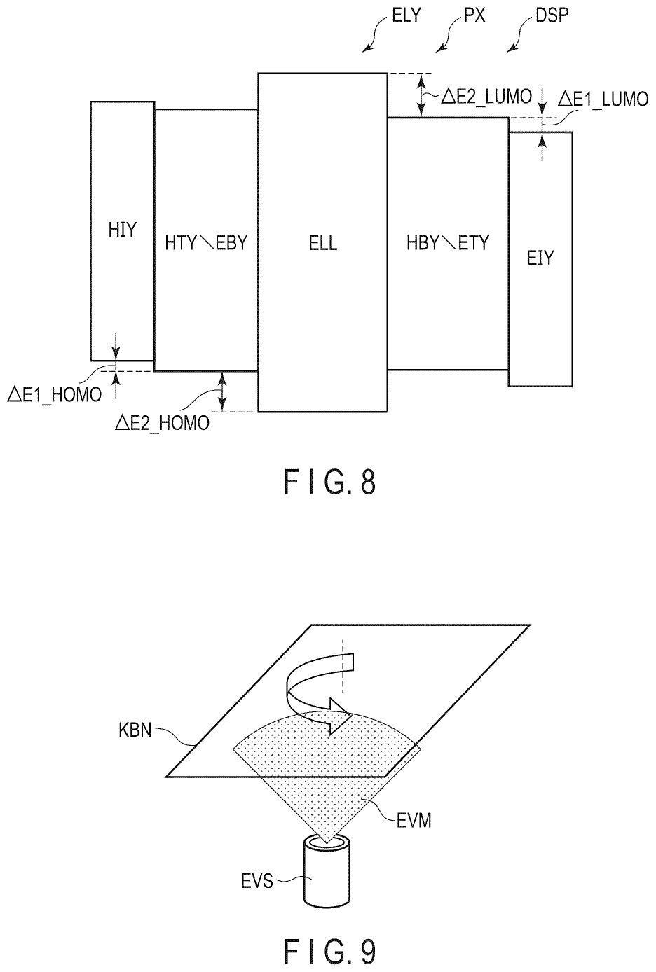

FIG. 7 is a diagram showing the energy bands of a display device having the staggered structure of this embodiment. FIG. 8 is a diagram showing the energy bands of a display device having a well-like structure of this embodiment.

In FIGS. 7 and 8, the HOMO level of the light emitting layer ELL is lower than the HOMO level of the adjacent carrier transport layers (a hole transport layer HTY and an electron blocking layer EBY, and an electron transport layer ETY and a hole blocking layer HBY). The LUMO level of the light emitting layer ELL is higher than the LUMO level of the adjacent carrier transport layers (a hole transport layer HTY and an electron transport layer ETY).

ΔE2_LUMO, which is the potential barrier between the electron transport layer ETY and the hole blocking layer HBY, and the light emitting layer ELL, and ΔE2_HOMO, which is the potential barrier between the hole transport layer HTY and the electron blocking layer EBY, and the light emitting layer ELL, will be referred to as ΔE2 when they are not particularly distinguished from each other. It is preferable that ΔE2 should be 0.1 eV or higher and 0.5 eV or lower (0.1 eV≤ΔE2≤0.5 eV). If ΔE2 is smaller than 0.1 eV (ΔE2<0.1 eV), carriers flow easily as described with reference to FIGS. 5 and 6. This results in a longer light emission lifetime of excitons and lower efficiency.

In order to make ΔE2 within the above-specified range, it suffices if a material that can make the light emitting layer ELL wide-gap (hereinafter referred to as “wide-gap material”) is co-deposited when depositing the light emitting layer ELL. In addition, to make ΔE2 fall within the above-specified range, for example, appropriate materials should be selected and the film thickness should be made appropriate.

ΔE1_LUMO, which is the potential barrier between the electron injection layer EIY, and the electron transport layer ETY and the hole blocking layer HBY, and ΔE1_HOMO, which is the potential barrier between the hole injection layer HIY, and the hole transport layer HTY and the electron blocking layer EBY, will be referred to as ΔE1 when they are not specifically distinguished from each other. ΔE1 should be 0.5 eV or less (ΔE1≤0.5 eV). Further, ΔE1 should be 0.35 eV or less (ΔE1≤0.35 eV). Furthermore, when ΔE1_LUMO≤0.2 eV, the best configuration can be obtained. ΔE1_LUMO is assumed based on that a work function of the common electrode CE in contact with the electron injection layer EIY is 3.5 eV.

The film thickness for confinement of carriers is affected by the lower one of the mobility of holes and that of electrons. Let us consider now, for example, the case where the mobility of electrons is lower than that of holes. When the mobility of electrons is 1×10⁻⁶ cm²/Vs, it is preferable that the film thickness should be 30 nm or more and 40 nm or less. When the mobility of electrons is 1×10⁻¹⁰ cm²/Vs, it is preferable that the film thickness should be 20 nm or more and 30 nm or less.

The hole injection layer HIY of this embodiment (see FIG. 4) contains a hole transport material and a p-type dopant. A usable example of the p-type dopant is 2-(7-dicyanomethylene-1,3,4,5,6,8,9,10-octafluoro-7H-pyrene-2-ylidene)-malononitrile (NDP-9). The concentration of the p-type dopant is 1.0%. The electron transport layer ETY of this embodiment contains an n-type carrier injection material. A usable example of the n-type carrier injection material is (8-hydroxyquinolinolato)lithium (Liq). The concentration of the n-type carrier injection material is 20%.

Incidentally, as deposition methods for forming the light-emitting layer ELL, a linear scan deposition method and a point source deposition method are known. In the point source deposition method, the deposition source is arranged in a single point shape. In the linear scan deposition method, the deposition sources are arranged in a linear shape and the film is deposited on the substrate by a process of sweeping from the short or long axis of the substrate to be deposited to the opposite axis.

FIG. 9 is a diagram showing the point source deposition method. Deposition material molecules EVM emitted from the evaporation source EVS, which is arranged in a single point shape, attach to the substrate KBN, to form a film. The uniformity of the film thickness is obtained by rotating the substrate KBN during the deposition. Generally, to form the light emitting layer ELL, a plurality of different materials are co-deposited. In the case of co-deposition, molecules of different deposition materials are released from a plurality of point deposition sources filled with different materials and are mixed between the deposition sources and the substrate. Then, the mixture is adhered to the substrate, thus forming a co-deposition film.

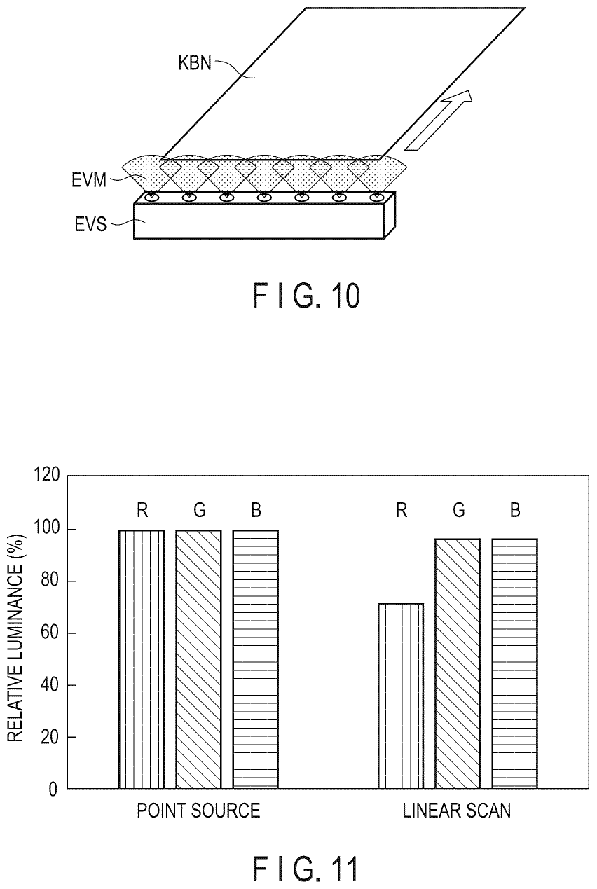

FIG. 10 is a diagram showing the linear scan deposition method. Deposition material molecules EVM emitted from the linearly arranged deposition sources EVS adhere to the substrate KBN to form a film. At this time, the deposition sources EVS are fixed and the substrate KBN is moved, or the substrate KBN is fixed and the deposition sources EVS are moved. In the case of co-deposition, molecules of respective deposition materials are released from a plurality of linear deposition sources filled with different materials and are mixed between the deposition source and substrate. Then, the mixture is attached to the substrate to form a co-deposition film.

The linear scan deposition method can deposit a large number of objects at once and therefore it is more productive and advantageous as compared to the point source deposition method. However, in the linear scan deposition method, such a large number of deposition sources are disposed in a linear pattern, and therefore the composition of the light emitting layer thus deposited may be separated into phases of different densities as compared to the point source deposition method. In such a light-emitting layer, the low-density phase and the high-density phase are separated to emit light.

FIG. 11 is a diagram illustrating the decrease in light emission efficiency. In FIG. 11, the relative luminance is shown for each of the light emitting layer emitting red color (R), the light emitting layer emitting green color (G) and the light emitting layer emitting blue color (B) in each of the point source deposition method and the linear scan deposition method.

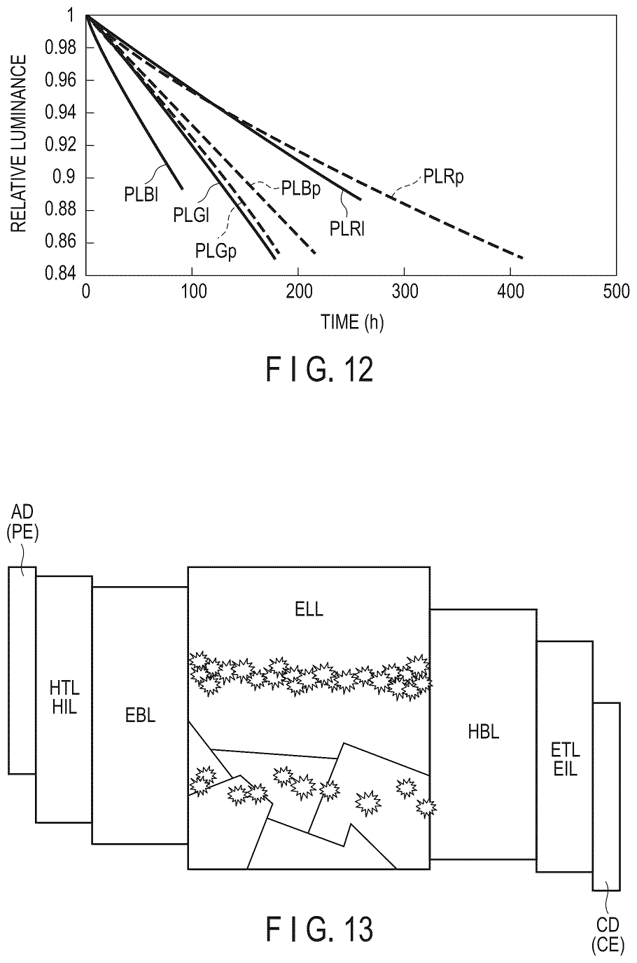

FIG. 12 is a diagram showing the luminance versus time in the configuration of the embodiment. The light emitting layer emits light in separate phases of low-density and high-density phases, the light emission efficiency decreases as shown in FIG. 11. Further, the light emission lifetime of the element decreases as shown in FIG. 12. According to this embodiment, it is possible to obtain a light emitting layer that emit uniform light. As a result, a significant improvement in the decrease in light emission efficiency as shown in FIG. 11 and an improvement in the decrease in lifetime as shown in FIG. 12 can be expected. As the element properties of the organic EL displays, the present invention can exhibit the advantages of improving the light emission efficiency by 10% to 30% and the lifetime by several percent.

For example, the phase separation can be obtained by hydrophobic molecules and hydrophilic molecules, or molecules having large particle size and those having small particle size. However, the composition does not simply differ between the point source deposition and the linear scan deposition methods, but coarseness and denseness can occur, which affects the properties. For example, in the compositions in which the current pathways are localized, the efficiency of the light-emitting layer emitting red color and the lifetime of the light emitting layer emitting blue color are significantly reduced.

In FIG. 12, as for the light-emitting layer emitting red, the light-emitting layer emitting green, and the light-emitting layer emitting blue, respectively, those formed by the point source deposition method are indicated as dotted lines and those formed by the linear scan deposition method are indicated as solid lines. The lateral axis in FIG. 12 represents the time (TIME) (h) from the start of light emission, and the vertical axis represents relative luminance (RELATIVE LUMINANCE).

The plot of the light from the light emitting layer that emits red, formed by the point source deposition method, versus time is referred to as PLRp. The plot of light from the light emitting layer that emits green versus time is referred to as PLGp. The plot of light from the light emitting layer that emits blue versus time is referred to as PLBp.

The plot of the light from the light emitting layer that emits red, formed by the linear scan deposition method versus time is referred to as PLR1. The plot of the light from the light emitting layer that emit green versus time is referred to as PLG1. The plot of the light from the light emitting layer that emits blue versus time is referred to as PLB1.

The light emitting layers formed by the linear scan deposition method each exhibits a steeper decrease in luminance versus time as compared to the light emitting layers formed by the point source deposition method. In particular, when comparing the blue plots PLBp and PLB1 with each other, it is seen that the decrease in the luminance of the plot PLB1 versus time is approximately twice as much as that of the plot PLBp. In other words, the lifetime of the light emitting layer that emits blue, formed by the linear scan deposition method is approximately half that of the light emitting layer that emits blue, formed by the point source deposition method.

FIG. 13 is a diagram showing that coarseness and denseness occur in the light emitting layer. In FIG. 13, the anode AD is the pixel electrode PE and the cathode CD is the common electrode CE.

The decrease in efficiency and lifetime shown in FIGS. 11 and 12 can be attributed to the localization of current pathways due to the occurrence of coarseness and denseness, as shown in FIG. 13. One factor that affects the light emission efficiency of the light emitting layer ELL is ΔE2_HOMO and ΔE2_LUMO. In the process of depositing the material of the light emitting layer ELL, when the first material MTL1 and the second material MTL2 of the light emitting layer ELL are co-deposited, a preferable technical method is to control the light emission characteristics of the light emitting layer ELL by adjusting ΔE2_HOMO and ΔE2_LUMO of the first material MTL1 and the second material MTL2. In this method, ΔE2_HOMO and ΔE2_LUMO of the first material MTL1 and the second material MTL2 are adjusted by controlling the compositions of the materials to be co-deposited. In the linear scan deposition method described above, the first material MTL1 and the second material MTL2 are separated into phases inside the material of the light emitting layer ELL by forming a low-density layer and a high-density layer, respectively, in the configuration seen in FIG. 13.

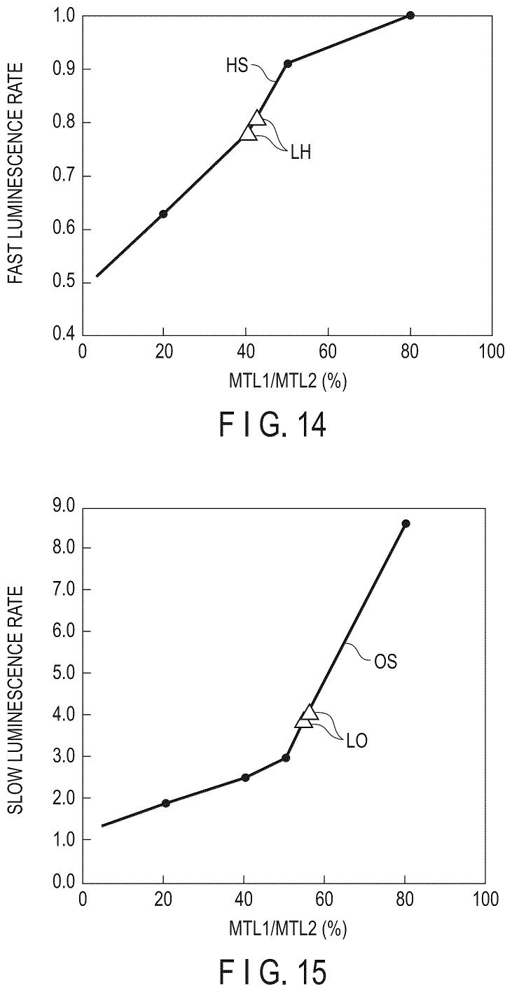

FIGS. 14 and 15 are diagram each showing calibration curves of light emission versus the compositions of the light emitting layer materials and are direct drawings indicating the occurrence of coarseness and denseness. In FIGS. 14 and 15, the lateral axis represents the ratio of the first material MTL1 to the second material MTL2 (MTL1/MTL2 (%)). The vertical axis in FIG. 14 represents the intensity of the luminescence of fast light emission in the light emitting layer ELL, FAST LUMINESCENCE RATE (unit: 1×10⁶/s). That is, it represents the increase in fast light emission in the light emitting layer ELL when the ratio of the first material MTL1 to the second material MTL2 within the light emitting layer ELL increases uniformly.

On the other hand, the vertical axis in FIG. 15 represents the SLOW LUMINESCENCE RATE (unit: 1×10⁶/s), the intensity of the luminance of the slow luminescence within the light emitting layer ELL. In other words, it represents the increase of slow luminescence within the light emitting layer ELL when the ratio of the first material MTL1 to the second material MTL2 within the light emitting layer ELL increases uniformly.

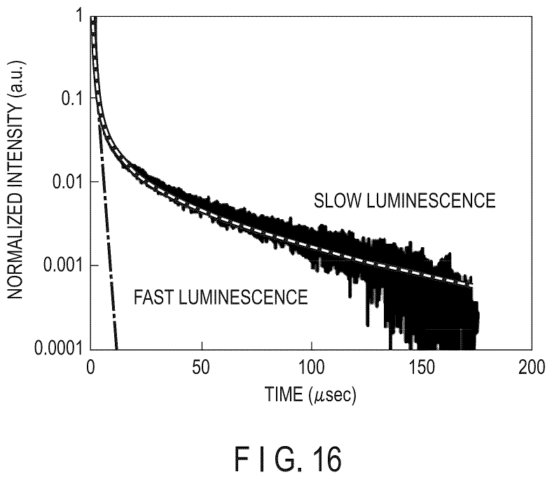

FIG. 16 is a diagram showing a time-resolved measurement of luminance. The vertical axis of FIG. 16 represents the luminance obtained from the light emitting layer ELL (NORMALIZED INTENSITY (a.u.)), and the lateral axis represents the time (TIME (μsec)). For the vertical axes of FIGS. 14 and 15, fast light emission and slow light emission can be estimated with the plots obtained using FIG. 16. The calibration curves in FIGS. 14 and 15 were created by plotting against the material ratio on the lateral axis.

The examples shown in FIGS. 14 and 15 show calibration curves at the time when the material of the light emitting layer that emits red phosphorescence is used as the deposition source and the light emitting layer is formed by the point source deposition method. In this case, the first material MTL1 and second material MTL2 described above are used as the deposition source. The first material MTL1 and the second material MTL2 are co-deposited to form the light emitting layer ELL. Here, the first material MTL1 is a wide-gap host material, which does not allow holes to flow easily and allows electrons to flow easily. For example, the hole mobility is 1×10⁻⁷ (cm²/Vs), the electron mobility is 5×10⁻⁵ (cm²/Vs), HOMO is 5.75 (eV) and LUMO is 2.7 (eV). The second material MTL2 is a material which allows holes to flow easily but does not allow electrons to flow easily. For example, the hole mobility is 4×10⁻⁵ (cm2/Vs), the electron mobility is 1×10⁻⁵ (cm²/Vs), HOMO is 5.7 (eV), and LUMO is 3.0 (eV). Here, the band gap of the first material MTL1 (3.05 eV) is larger than that of the second material MTL2 (2.7 eV). The band gap is the difference between the HOMO and LUMO in each material.

The material of the light emitting layer contains a low-density component and a high-density component. The low-density component has characteristics of fast light emission, whereas the high-density component has characteristics of slow light emission. FIG. 14 shows the calibration curve of the low-density component HS.

In FIG. 14, further, the light emission of the light emitting layer formed by the linear scan deposition method is indicated by white triangles and a reference symbol LH. In the low-density component HS, when the ratio of the first material MTL1 to the second material MTL2 is 40% (MTL1/MTL2=40(%)), light emission is generated in the light emitting layer formed by the linear scan deposition method.

FIG. 15 shows a calibration curve for the high-density component OS. In FIG. 15 as well, the light emission of the light emitting layer formed by the linear scan deposition method is indicated by white triangles and a reference symbol LO. In the high-density component OS, when the ratio of the first material MTL1 to the second material MTL2 is 60% (MTL1/MTL2=60(%)), light emission is generated in the light emitting layer formed by the linear scan deposition method.

As can be seen from the calibration curves in FIGS. 14 and 15, when the light emitting layer formed by the point source deposition method is made so that the ratio of the first material MTL1 to the second material MTL2 is at an average of 50% (MTL1/MTL2=50%), the low-density component HS emits light at 50% and the high-density component OS emits light at 50%. When the film is deposited so that the average ratio is 30%, the low-density component HS emits light at 30% and the high-density component OS as well emits light at 30%. On the other hand, as to the light emitting layer formed by the linear scan deposition method, even if the film is formed so that the ratio of the first material MTL1 to the second material MTL2 is at an average of 50% (MTL1/MTL2=50%), the low-density component HS and the high-density component OS emit light at 40% and 60%, respectively, indicating that the low-density component HS and the high-density component OS emit light at different composition ratios.

The fast light emission generated by the low-density component HS is referred to as instantaneous light emission (PROMPT) and is more efficient as compared to the other. The slow light emission generated by the high-density component OS is referred to as delayed light emission (DELAYED LUMINESCENCE) and is less efficient due to the influence of a non-light emitting component referred to as up-conversion. When the light emitting layer formed by the linear scan deposition method described above is made so that the average ratio is 50% (MTL1/MTL2=50%), the light emission of the low-density component HS, which is highly efficient, is reduced by 10% and that of the high-density component OS, which is less efficient, is increased by 10%. Therefore, it is preferable that the low-density component HS and the high-density component OS should not be made to emit light at different composition ratios. In the light of the above, the light emitting layer should be deposited with a composition that causes a less effect even if it moves from the center (50%) to the left or right. In this manner, it is possible to enable the light-emitting layer formed by the linear scan deposition method to generate uniform light emission regardless of the low-density component HS (fast light emission) and the high-density component OS (slow light emission).

In the embodiment, the ratio of the first material MTL1 to the second material MTL2 is set to 5% or more and less than 40% (5%≤MTL1/MTL2<40%), more preferably, 5% or more and 30% or less (5%≤MTL1/MTL2≤30%), or even more preferably, 5% or more and 20% or less (5%≤MTL1/MTL2≤20%). By taking such a material ratio, it is possible to obtain a light-emitting layer that generates uniform light emission.

Further, as to the chromaticity of red color, CIEx=0.635 and CIEy=0.315, as to that of green color, CIEx=0.227 and CIEy=0.717, and as to that of blue color, CIEx=0.141 and CIEy=0.05. Note that CIEx, CIEy and CIEy play important roles in designing of the pixels for red, green and blue colors, respectively.

In the embodiment, red phosphorescence is described as an example, but as for blue fluorescence, due to the phase separation, a non-uniform light emitting layer results as in the case of red phosphorescence. Here, by taking the above-described ratios for the material, it is possible to obtain a light-emitting layer that generates uniform light emission.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an anode;
an organic EL layer including a hole injection layer, a hole transport layer, an electron blocking layer, a light emitting layer, a hole blocking layer, an electron transport layer and an electron injection layer; and
a cathode, wherein
ΔE1_LUMO is defined as a potential barrier between the electron injection layer, and the electron transport layer and the hole blocking layer,
ΔE1_HOMO is defined as a potential barrier between the hole injection layer, and the hole transport layer and the electron blocking layer,
each of ΔE1_LUMO and ΔE1_HOMO is 0.35 eV or less (ΔE1≤0.35 eV),
ΔE2_LUMO is defined as a potential barrier between the electron transport layer and the hole blocking layer, and the light emitting layer,
ΔE2_HOMO is defined as a potential barrier between the hole transport layer and the electron blocking layer, and the light emitting layer,
each of ΔE2_LUMO and ΔE2_HOMO is 0.1 eV or more and 0.5 eV or less (0.1 eV≤ΔE2≤0.5 eV),
the light emitting layer includes a first material and a second material,
a band gap of the first material is larger than a band gap of the second material, and
a ratio of the first material to the second material is 5% or more and less than 40%.

2. The display device according to claim 1, wherein
the ratio of the first material to the second material is 5% or more and 30% or less.

3. The display device according to claim 1, wherein
the ratio of the first material to the second material is 5% or more and 20% or less.

4. The display device according to claim 1, wherein
the ΔE1_LUMO is 0.2 eV or less.

5. The display device of claim 1, wherein
the band gap of the first material is 3.05 eV and the band gap of the second material is 2.7 eV.

6. A method for manufacturing a display device, wherein
the display device comprises
an anode;
an organic EL layer including a hole injection layer, a hole transport layer, an electron blocking layer, a light emitting layer, a hole blocking layer,
an electron transport layer and an electron injection layer; and
a cathode,
ΔE1_LUMO is defined as a potential barrier between the electron injection layer, and the electron transport layer and the hole blocking layer,
ΔE1_HOMO is defined as a potential barrier between the hole injection layer, and the hole transport layer and the electron blocking layer,
each of ΔE1_LUMO and ΔE1_HOMO is 0.35 eV or less (ΔE1≤0.35 eV),
ΔE2_LUMO is defined as a potential barrier between the electron transport layer and the hole blocking layer, and the light emitting layer,
ΔE2_HOMO is defined as a potential barrier between the hole transport layer and the electron blocking layer, and the light emitting layer,
each of ΔE2_LUMO and ΔE2_HOMO is 0.1 eV or more and 0.5 eV or less (0.1 eV≤ΔE2≤0.5 eV),
the light emitting layer includes a first material and a second material,
a band gap of the first material is larger than a band gap of the second material,
a ratio of the first material to the second material is 5% or more and less than 40%, and
the method comprising:
forming the light emitting layer by a linear scan evaporation method using a linearly arranged evaporation sources.

7. The method according to claim 6, wherein
the ratio of the first material to the second material is 5% or more and 30% or less.

8. The method according to claim 6, wherein
the ratio of the first material to the second material is 5% or more and 20% or less.

9. The method according to claim 6, wherein
the ΔE1_LUMO is 0.2 eV or less.

10. The method according to claim 6, wherein
the band gap of the first material is 3.05 eV and the band gap of the second material is 2.7 eV.
